(19) United States
(12) Patent Application Publication
(10) Pub. No.: US 2012/0175476 A1
(43) Pub. Date: Jul. 12, 2012

(54) MONITOR SUPPORT ARM

(75) Inventors: Alex Lau, Barnes (GB); Andrew Wills, Dulwich (GB)

(73) Assignee: COLEBROOK BOSSON SAUNDERS PRODUCTS LTD., London (UK)

(21) Appl. No.: 12/296,784

(22) PCT Filed: Apr. 13, 2007
(86) PCT No.: PCT/EP07/53644

§ 371 Date: Sep. 23, 2009

(30) Foreign Application Priority Data
Apr. 13, 2006 (GB) 0607484.3

(51) Int. Cl. H05K 7/00

(52) U.S. Cl. 248/218.4

(57) ABSTRACT

A monitor support (1) is disclosed and comprises a primary support member (4) for attachment to a post, wall or other mounting surface, a rigid link arm (6) extending from the primary support member for rotation relative to the primary support member about a first pivot axis (27) in a vertical plane, a secondary support member (7) attached to the free end of the link arm for rotation of the secondary support member relative to the link arm about a second pivot axis (42) parallel to the first pivot axis and, a flexible control element (25) extending between the primary and secondary support members spaced from the first and second pivot axes respectively. The monitor support is configured so that the control element causes the secondary support member to rotate relative to the link arm about the second pivot axis as the link arm rotates relative to the primary support member about the first pivot axis so as to maintain the same relative orientation of the primary and secondary support members.

The present invention relates to a monitor support arm primarily for a flat screen display panel such as a computer screen or LCD television.

Monitor support arms for supporting flat screen computer monitors are known and enable a user to adjust a monitor mounted to the arm over a range of vertical and horizontal angles so that it can be moved into a desired working position to suit. The ability to move a monitor easily into any desired position is important as it minimises eye strain and may alleviate or prevent back or other bodily pain which may arise as a result of sitting at an improperly positioned workstation over a period of time.

A monitor support generally has an elongate link arm pivotally attached to a support element at a first end which cooperates with a support post upstanding from a desk or other surface. Alternatively, the support element may be attached to a vertical surface such as a wall or partition. A mounting plate that complies with the VESA screen mounting standards is attached to the opposite or second end of the arm via a universal or pivot joint for attachment of a computer monitor in the usual way. Alternatively, the arm may have a secondary limb extending from and pivotally attached to its free end opposite the support element, in which case the mounting plate is attached to the remote end of the secondary limb so that the screen may be manipulated into a wide range of different positions and orientations.

It is known to provide a monitor support arm with a four bar or parallelogram linkage configuration to maintain a constant orientation of the computer screen as the arm pivots in a vertical plane to alter its height. It is also known to provide a gas strut to support the load of the monitor and the weight of the four bar linkage assembly and facilitate the easy adjustment of the monitor. The gas strut extends from and is pivotally attached to the support element and its other end is pivotally connected to the remote end, or close to the remote end, of an elongate link arm that also extends from and is pivotally attached to the support element spaced above the point at which the gas arm is pivotally connected to the support element. The distance between the point at which the gas arm is pivotally connected to the support element and the point at which the elongate link arm is pivotally connected to the support element is adjustable to compensate for monitors of different weights supported on the end of the arm. As the distance between the pivots decreases and the angle between the gas arm and the elongate link arm reduces, the load provided by the gas arm decreases to assist in counterbalancing a lighter weight monitor because a greater component of the force provided by the gas strut is acting along the link arm as opposed to in a vertical direction. However, if the distance between the pivots increases and the angle between the gas arm and the elongate link arm increases, the load provided by the gas arm increases to counterbalance a heavier weight monitor, because a greater component of the force provided by the gas strut is acting in a vertical direction than in a direction along the link arm. When a monitor has been attached to the arm and the counterbalance adjustment has been made, no clamping mechanism is required to hold the screen in a desired position. The monitor can therefore be raised or lowered to move it into the desired position without having to release a clamp and carry the entire weight of the monitor during the adjustment. It will be appreciated that after the initial set-up, no further load adjustment of the gas strut is required unless the monitor is replaced for one of a different weight.

A typical four bar linkage assembly comprises a primary support bracket at one end which remains stationary and is attached to a support post or other supporting surface and, a secondary support bracket at the opposite end for movement in a vertical plane to adjust the height of a monitor attached to it. The primary and secondary support brackets are coupled together by a first or upper link arm which is pivotally attached at one end to the primary support bracket and at the other end to the secondary support bracket. Similarly, a second or lower link arm is pivotally attached at one end to the primary support bracket and at the other end to the secondary support bracket. The pivotal connection of the upper and lower link arms to each of the primary and secondary support brackets are spaced from each other in the vertical direction so that the upper and lower link arms are spaced from but parallel to each other. As the upper and lower link arms pivot about their respective pivots on the primary support bracket to lower or raise the secondary support bracket, they also pivot about their pivots on the secondary support bracket so that the secondary support bracket maintains the same parallel orientation or geometry as the primary support bracket. As has been explained above, a gas strut extends between and is pivotally connected to the primary support bracket and to the upper link arm close to or at its point of connection to the secondary support bracket to counterbalance the support arm and prevent it from dropping under the weight of the monitor. The pivotal connection of the gas strut to the primary support element can be moved closer to, or away from, the pivotal point of attachment of the upper link arm to the primary support element, to alter the counterbalancing load provided by the gas strut.

A disadvantage with the conventional four bar linkage arrangement is that they are generally unattractive and complicated and present a number of areas where fingers could become trapped or pinched during height adjustment.

The present invention seeks to provide an improved monitor support arm which overcomes or substantially alleviates the disadvantages mentioned above, which reduces the total number and overall weight of the components of the device and improves its appearance.

A monitor support according to the present invention comprises a primary support member for attachment to a post, wall or other mounting surface, a rigid link arm extending from the primary support member for rotation relative to the primary support member about a first pivot axis in a vertical plane, a secondary support member attached to the free end of the link arm for rotation of the secondary support member relative to the link arm about a second pivot axis parallel to the first pivot axis and, a flexible control element extending between the primary and secondary support members spaced from the first and second pivot axes respectively, the monitor support being configured so that the control element causes the secondary support member to rotate relative to the link arm about the second pivot axis as the link arm rotates relative to the primary support member about the first pivot axis so as to maintain the same relative orientation of the primary and secondary support members.

It will be appreciated that the monitor support arm of the present invention employs the principles of a four-bar linkage assembly but may do so without the use of multiple pivotal connections between the linkages and the supporting elements thereby providing a simple device with a more aesthetic appearance and smooth adjustment.

In a preferred embodiment, the support comprises a pair of parallel link arms, both link arms being mounted to the primary and secondary support members for rotation about the first and second axes respectively, and so as to be spaced from each other in an axial direction.

Preferably, the primary and secondary support members extend between and space the parallel link arms from each other in said axial direction.

The parallel link arms may be configured so that the flexible control element is disposed in the space between said parallel arms and the parallel link arms at least partially conceal said flexible control element.

The parallel link arms may advantageously include upstanding walls extending into the space between said parallel link arms to provide support for the control element extending between the primary and secondary support members.

In one embodiment, a pair of flexible control elements extend between the primary and secondary support members, said flexible control elements being spaced from each other in an axial direction so that each control element lies adjacent to one of said parallel link arms.

The control element is preferably spaced above a line extending between the first and second pivot axes and, a second flexible control element extends between the primary and secondary support members spaced below a line extending between the first and second pivot axes.

In another embodiment the monitor support comprises a first pair of flexible control elements spaced above a line extending between the first and second pivot axes and, a second pair of flexible control elements extending between the primary and secondary support members spaced below a line extending between the first and second pivot axes.

In a particularly preferred embodiment, the flexible control element is endless and extends around both the primary and secondary support members.

The primary support member may include a control element guide to receive and guide the cable around the primary support member. The control element guide can be at least partially arcuate in shape so that the control element follows a curved path around the primary support member.

Similarly, the secondary support member may include a control element guide to receive and guide the control element around the secondary support member. The control element guide may be at least partially arcuate in shape so that the control element follows a curved path around the secondary support member.

In the most preferred embodiment, the control element is looped around the primary and secondary support members and comprises at least one upper run that extends between the primary and secondary support members and at least one lower run that extends between the primary and secondary support members.

The primary support member may be configured such that the lower run intersects a vertical plane extending through the first pivot axis at a distance below the first pivot axis and the upper run intersects said vertical plane at a distance above said first pivot axis. Similarly, the secondary support member may be configured so that the lower run intersects a vertical plane extending through the second pivot axis at a distance below the second pivot axis and the upper run intersects said vertical plane at a distance above the second pivot axis.

Preferably, the control element loop is elongated to form two curved ends, an intermediate section between said ends passing around the primary support member with the two curved ends hooked over the secondary support member so that the control element has two upper and two lower runs extending between the primary and secondary support elements.

In one embodiment the support may include a control element adjustment mechanism for tensioning the control element which can be mounted on the primary support member. The primary support member preferably includes a recess extending substantially at right angles to the direction of the run of the control element so that the control element bridges the mouth of the recess as it extends over the primary support element.

The tension adjustment mechanism preferably includes a tensioning member which can be drawn into the recess against the control member, once a control element has been positioned so as to extend over the mouth of the recess, to pull the control element into the recess to tension the control element.

The tension adjustment mechanism may include a threaded rod in engagement with the primary support element that extends beyond the mouth of the recess, the tensioning member being threadingly engaged with the rod so that a control element extending over the mouth of the recess is engaged by the tensioning member as the rod is rotated and the tensioning member is drawn into the recess against the control member.

In a preferred embodiment, a gas strut extends between the primary and secondary support elements. One end of the gas strut is preferably coupled to a shaft extending coaxial with the first pivot axis on the primary support member. The monitor support may advantageously include a hook member attached to an end of the gas strut to connect the gas strut to the shaft.

One end of the gas strut is preferably pivotally attached to a load adjustment member coupled to the secondary support member and the load adjustment member is configured to enable said end of the gas strut coupled to it to be moved towards or away from the second pivot axis to adjust the load provided by the gas strut.

In a preferred embodiment, a threaded rod extends through the secondary support member and into the load adjustment member so that rotation of said threaded rod moves the end of the gas strut pivotally coupled to the load adjustment member towards or away from the second pivot axis.

The link arm and the secondary support element advantageously includes cooperating members to limit the rotation of the arm in said vertical plane to within a predetermined angle.

In one embodiment, the cooperating members comprise a boss on the secondary support element which locates in an arcuately shaped guide groove in the link arm so that rotation of the arm is limited by the extent of the guide groove.

The secondary support element may include a mounting shaft for the pivotal attachment of a secondary arm thereto, the monitor being attachable to the free end of the secondary arm.

In a preferred embodiment, the flexible control element is a cable. Alternatively, the flexible control element could be a belt.

Embodiments of the invention will now be described, by way of example only, and with reference to the accompanying drawings, in which:

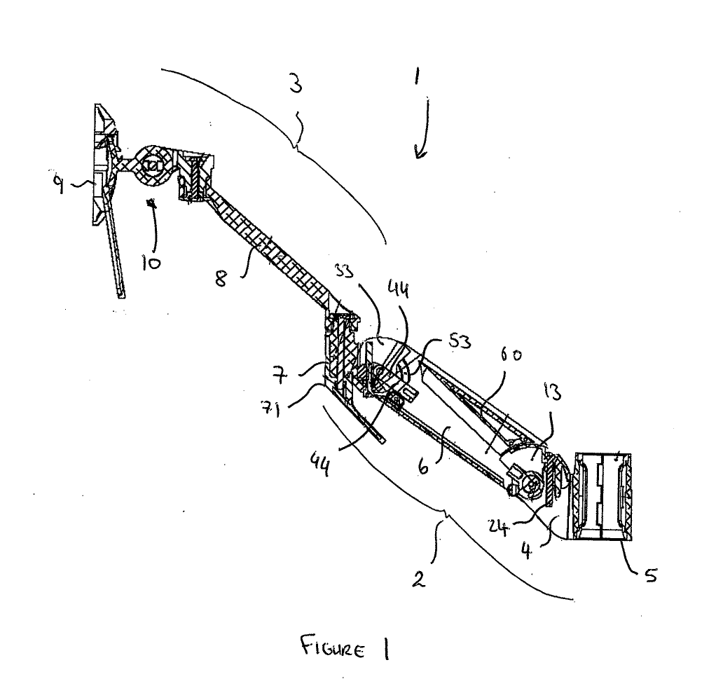

FIG. 1 is an assembled side sectional view of a monitor support arm according to one embodiment of the present invention;

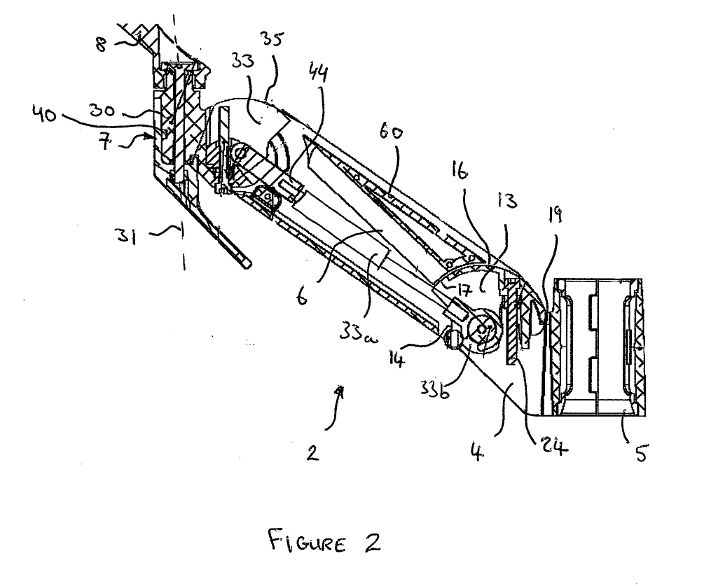

FIG. 2 is an enlarged side sectional view of the first section of the monitor support arm shown in FIG. 1;

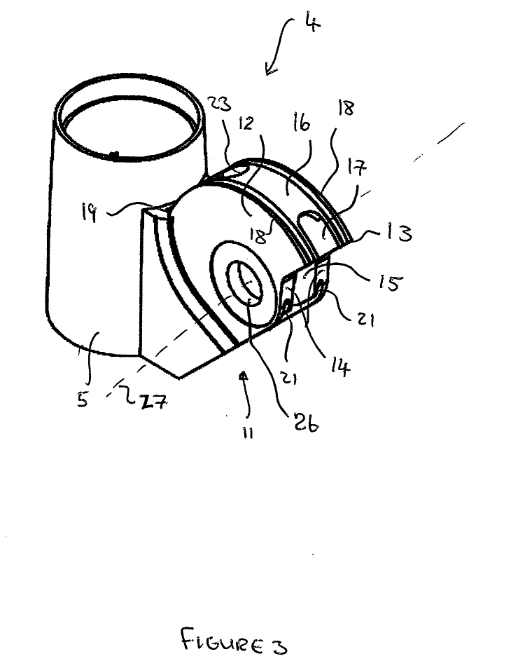

FIG. 3 is a perspective view of the primary support element of the monitor support arm;

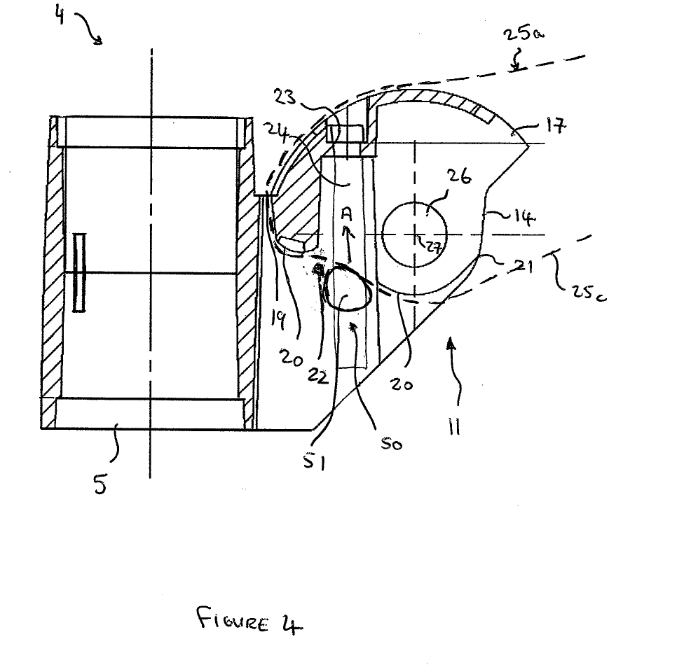

FIG. 4 is a side sectional view of the primary support element shown in FIG. 3;

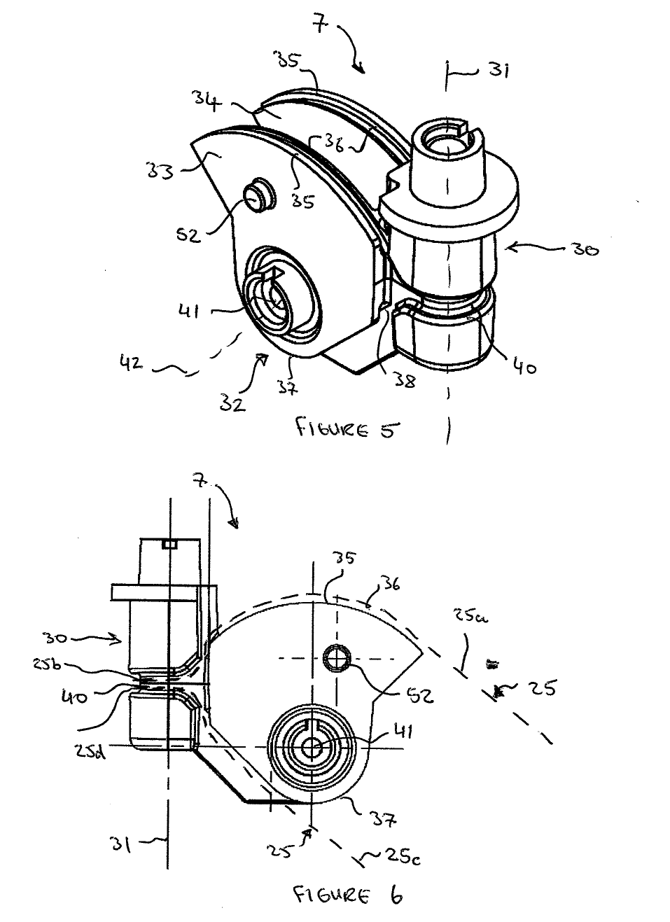

FIG. 5 is a perspective view of the secondary support element of the monitor support arm;

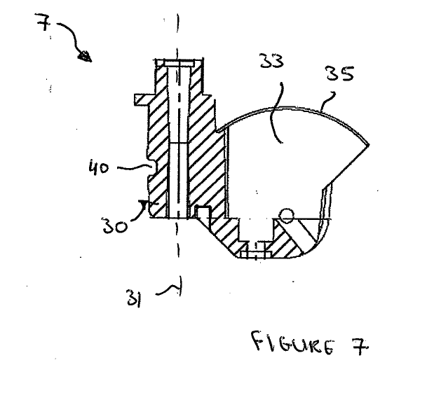

FIG. 6 is a side view of the secondary support element as shown in FIG. 5;

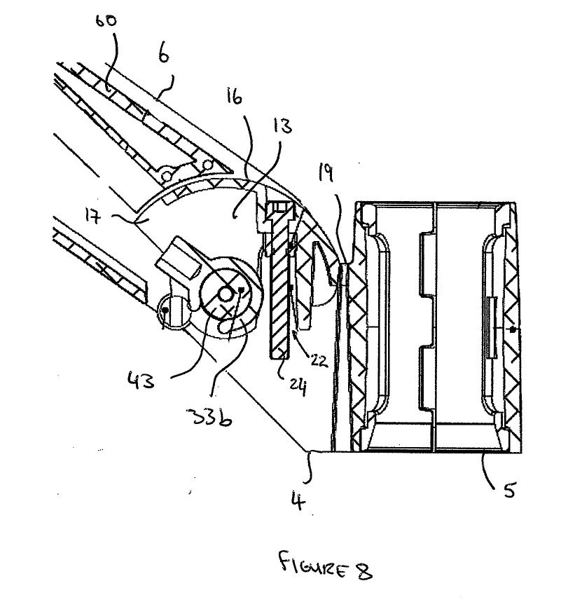

FIG. 7 is a side sectional view of the secondary support element shown in FIGS. 5 and 6;

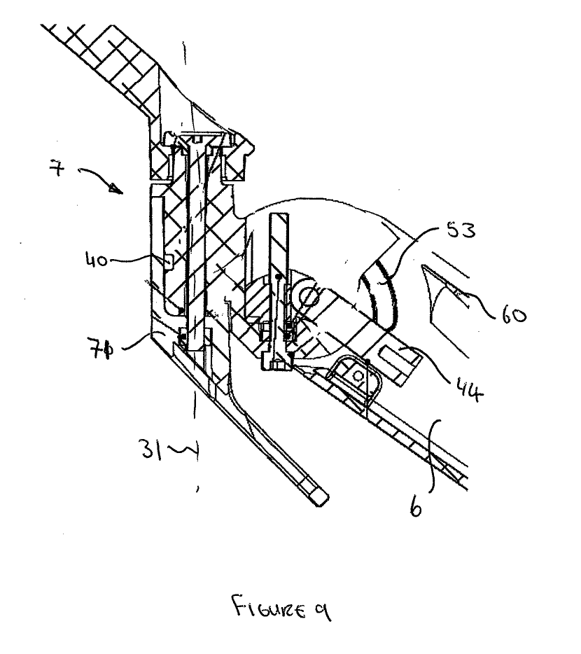

FIG. 8 is an enlarged side sectional view of a portion of the monitor support arm primarily illustrating the primary support element shown in FIGS. 1 and 2 and its connection to the link arms;

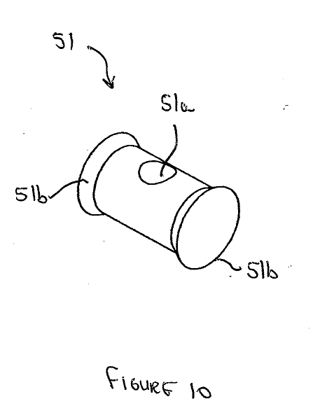

FIG. 9 is an enlarged side sectional view of a portion of the monitor support arm primarily illustrating the secondary support element shown in FIGS. 1 and 2 and its connection to the link arms; and

FIG. 10 is a perspective view of the cable tensioning member of the cable adjustment device.

Referring now to the drawings, there is shown in FIG. 1 a monitor support arm 1 according to an embodiment of the present invention comprising first and second sections 2, 3. The first section 2 includes a primary support member 4 to enable the monitor support arm 1 to be attached to a fixed support such as a mounting post (not shown) upstanding from a desk or workstation. The primary support member 4 illustrated in FIG. 1 includes a sleeve 5 which may be slid over a cylindrical support post to couple the primary support member 4 to the post. A pair of spaced parallel link arms 6 (only one of which is shown in FIG. 1—the other having been removed for clarity) are pivotally attached to and extend from the primary support member 4 for rotation about a first axis 27 and a secondary support member 7 is coupled to the free end of the parallel link arms 6 for rotation relative to the link arms 6 about a second axis 42. Each link arm 6 is mounted for rotation about the same axis namely, for rotation about the first axis 27 with respect to the primary support member 4 and, for rotation about the second axis 42 with respect to the secondary support member 7. A portion of each of the primary and secondary support members 4,6 extends between the two parallel link arms 6 and spaces them from each other. The link arms 6 may generally take the form of substantially flat plate-like members.

The second section 3 comprises a secondary arm 8 pivotally connected at one end to the secondary support member 7 and having a flat screen mounting plate 9 attached to its other end remote from the secondary support member 7 by a universal or similar type pivot joint 10.

It will be appreciated that the secondary arm 8 is not an essential part of the invention and the flat screen mounting plate 9 could be attached directly to the secondary support member 7 via a pivot or universal joint 10, instead. The present invention is primarily concerned with the first section 2, illustrated more closely in FIG. 2, and so the second section 3, including the universal joint 10 and the mounting plate 9, will not be described in any significant detail in the present application.

The primary support member 4 is shown more clearly in FIGS. 3 and 4 and from which it can be seen that it includes a link arm mounting portion 11 extending radially from the outer surface of the sleeve 5. The mounting portion 11 comprises a pair of spaced parallel walls 12, 13 extending from and integrally formed together with the sleeve 5. The parallel walls 12, 13 have a front edge 14 and define a space 15 therebetween. An arcuately shaped top wall portion 16 extends between the walls 12, 13 to join them together and serves to partially enclose the space 15 between the walls 12, 13. A front section 17 of the top wall 16 is cut away where it meets the front edge 14 to allow the strut of a gas arm 33a (see FIG. 2—the gas arm 33a is not shown in FIG. 1) to pass into the space 15 between the walls 12, 13.

The top wall potion 16 has a pair of parallel spaced arcuately shaped guide grooves 18 formed therein adjacent to each of the parallel walls 12, 13 to receive and guide a control element which, in the preferred embodiment, is a cable 25 (see FIG. 4). However, it will be appreciated that the control element could also take the form of a belt or other flexible element. The grooves 18 extend around the surface of the top wall 16 and through a gap 19 between the sleeve 5 and the mounting portion 11. Ridges 20 (see FIG. 4) are formed on the inner surface of each wall 12, 13 and the grooves 18 extend along the surface of these ridges 20 before terminating at mouths 21 where they meet the front edge 14 of the mounting portion 11. A portion 22 of each inner wall surface is not ridged so that the cable seated in the guide grooves 18 span this unridged portion 22 without being supported by guide grooves 18, as shown in FIG. 4. An aperture 23 is formed in the top wall portion 16 and a threaded rod or bolt 24 extends through this aperture 23 and down between the unridged portion 22, for reasons that will be explained.

The outer surface of each wall 12, 13 provides a mounting surface for link arms 6 which are coupled to the outside of each wall 12, 13 using a fastening member such as a bolt (not shown) that extends through an aperture 26 in each wall 12, 13 so as to pivotally mount the arms 6 for rotation relative to the primary support member 4 about a first pivot axis 27 coaxial with the aperture 26 in each wall 12, 13. It will be appreciated that both link arms 6 are pivotally mounted to each wall 12,13 of the primary support member 4 for rotation about the same pivot axis 27 and are spaced from each other by the distance between the outer surface of each wall 12, 13.

The secondary support member 7 is illustrated in FIGS. 5 to 7 and comprises a shaft portion 30 to which the second section 3 is pivotally mounted for rotation about a vertical axis 31 extending through the shaft portion 30 and a mounting portion 32 which is integrally formed with the shaft portion 30 and extends in a substantially radial direction from the shaft portion 30. The mounting portion 32 comprises a pair of spaced parallel walls 33, 34 each having an arcuate upper wall surface 35 in which upper guide grooves 36 are formed and lower surfaces 37 in which lower guide grooves 38 are formed. The outer generally cylindrically shaped wall 39 of the shaft portion 30 also has a curved circumferentially extending recess 40 extending around the shaft portion 30 from one wall 33 to the other wall 34 so that the upper and lower guide grooves 36, 38 and the recess 40 substantially blend into each other and so that the control cable 25 can pass along the upper guide grooves 36 and around the shaft portion 30 and also along the lower guide grooves 38 and around the shaft portion 30, as shown in FIG. 6.

Each spaced parallel wall 33, 34 has an aperture 41 therein to receive and pivotally attach the opposite end of each of the link arms 6 to the outer surface of each wall 33, 34, using a bolt (not shown) that extends through both the walls 33, 34 and both the link arms 6, so that the secondary support member 7 and the link arms 6 pivot together with respect to the first axis 27 and the secondary support member 7 can pivot relative to the link arms about a second axis 42 extending through the aperture 41. It will be appreciated that both link arms 6 are mounted to the secondary support member 7 for rotation about the same pivot axis 42.

The secondary support member 7 may include a cable guide member 71 that attaches to the shaft portion 30.

The spacing between the walls 12, 13 of the primary support member 4 and the walls 33,34 of the secondary support member 7 is substantially the same so that, when the ends of each of the link arms 6 are pivotally attached to each wall 12,13,33,34 of the primary and secondary support members 4, 7, they are parallel to each other and the grooves 18,20,36,38 in the primary and secondary support members 4,7 are in alignment so that the control cable 25 extends between the primary and secondary support members 4,7 parallel to the link arms 6. The link arms 6 extend in a vertical direction so that the control cable 25 is disposed between them and is at least partially concealed by the link arms 6, at least when the monitor support is viewed from the side, in the direction as illustrated in FIG. 1. A covering strip or insert (not shown) may locate between the link arms 6 to enclose the space between them and completely conceal at least the portion of the cable 25 that extends between the primary and secondary support members, from view.

The gas strut 33a extends between the primary and secondary support members 4,7 and is also concealed by the link arms 6. One end of the gas strut 33a which is coupled to the primary support member 4 is provided with a hooked element 33b (see FIGS. 2 and 8) which locates around a shaft 43 which is coaxial with the bolt (not shown) extending through the first pivot axis 27 to attach the end of the gas strut 33a to the primary support member 4 between its walls 12, 13. Similarly, the other end of the gas strut 33a is pivotally coupled to a load adjustment member 44 attached to the secondary support member 7 between the walls 31, 32. Adjustment of the load provided by the gas strut 33a is achieved by moving the load adjustment member 44 either towards, or away from, the second pivot axis 42 in a vertical direction so that the pivotal connection of the gas strut 33a to the load adjustment member 44 moves closer to, or away from, the second pivot axis 42. As the pivotal connection of the gas strut 33a moves closer to the second pivot axis 42, a vertical component of the load provided by the gas strut 33a is reduced so as to counterbalance a monitor of lighter weight attached to the monitor support. However, when the pivotal connection of the gas strut 33a moves further away from the second pivot axis 42, the vertical component of the load provided by the gas strut 33a increases so as to counterbalance a monitor of greater weight mounted to the monitor support. This avoids the need to provide any sort of clamping mechanism to hold the monitor at a selected height and prevent it from dropping under its own weight.

It will be appreciated that the gas strut acts applies a force to the secondary support member 7 which would cause it to rotate about the second pivot axis 42 (in an anti-clockwise direction as shown in FIG. 2). This rotation is prevented or counteracted by the tension in the cable 25 which extends over the secondary support element and applies a force acting in the opposite direction to prevent its rotation. As the point of connection of the gas strut 33a to the secondary support element 7 is moved closer to the second pivot axis 42, the rotational force acting on the secondary support element 7 decreases and increases as the point of connection of the gas strut 33a is moved further away from the second pivot axis, thereby enabling adjustment of the load to compensate for monitors of different weights. This arrangement is different from a conventional arm in which the force applied by the gas strut does not impart a rotational force to the secondary support element.

In the preferred, and illustrated, embodiment, the control cable 25 is endless extends between and around both the primary and secondary support elements 4,7 and is configured so as to cause the secondary support element 7 to rotate relative to the link arms 6 about the second pivot axis 42 as the link arms 6 rotate relative to the primary support element 4 about the first pivot axis 27 so as to maintain the same relative orientation or geometry between the primary and secondary support elements 4,7. Effectively, the control cable 25 acts together with the link arms 6 and the primary and secondary support members 4,7 as a parallelogram linkage assembly.

A portion of the cable 25 is shown in dashed lines in FIGS. 4 and 6 for clarity. In the preferred embodiment, the control cable 25 consists of a single elongated endless loop having an intermediate section that passes around the primary support element 4 and has an upper cable run 25a extending from the primary support element 4 above the first pivot axis to a first end 25b which is hooked over the secondary support element 7 and, a second lower cable run 25c extending from the primary support element 4 below the first pivot axis 27 to a second end 25d which is also hooked over the secondary support element 7 in the same way as the first end 25b.

The first and second ends 25b,25d of the cable loop 25 are received in and meet within the recess 40 formed in the shaft portion 30. The lower cable run 25c passes alongside either side of the shaft portion 30 and into the guide grooves 38 in each lower surface of the secondary support element 7 and then spans the space between the primary and secondary support elements 4,7 substantially unsupported, although a shoulder or supporting wall 60 may be formed on the inner surface of each link arm 6 which extends into the space between the link arms 6 and at least part of the upper and/or lower run may lie over or at least contact the shoulder 60 so as to be partially supported by it. When the lower cable run 25c reaches the primary support element 4 it passes into the mouth 21 of the lower guide grooves 18 formed in the ridges 20 on the inner wall surface and bridges the break in the ridges 20 before passing up through the aperture 19 between the sleeve 5 and the mounting portion 11 and over the top wall 16 before the upper cable run 25a spans the gap between the primary and secondary support elements 4,7 before passing into the upper guide grooves 36 in the upper wall 35 of the secondary support member 7 before being hooked over the shaft portion 30 and retained in the recess 40 adjacent to the first end 25b.

It will therefore be appreciated that there two upper parallel cable runs 25a and two lower parallel cable runs 25c extending between the primary and secondary support elements 4,7. It will also be appreciated that the cable 25 meets the primary and secondary support elements 4,7 at a distance from the first and second pivot axes 27,42.

The primary support element 4 includes a cable tensioning mechanism 50 to draw the cable 25 tightly against the primary and secondary support elements 4,7 and prevent any slippage or play between components. It will be appreciated that the cable tensioning mechanism 50 could also, or alternatively, be provided on the secondary support element 7 instead of the primary support element 4.

As mentioned above, a threaded rod or bolt 24 extends through the aperture 23 in the top wall 16 of the mounting portion 11 of the primary support element 4 and beyond the mouth 22 of the break between the ridges 20 formed on the inner surface of the walls 12, 13. A cylindrical cable capture member 51, illustrated in FIGS. 4 and 10 but omitted from FIG. 8, is threadingly engaged on the bolt 24 so that, as the bolt 24 is rotated in one direction, the cable capture member 51 moves further along the rod 24 and is drawn further inwards in the direction indicated by arrow A in FIG. 4 so that the portion of the cable spanning the gap between the break in the ridges 20 is pulled upwards or drawn into the gap between the ridges 20 thereby tensioning the cable 25 extending around both the primary and secondary support elements 4,7. Rotating the bolt 24 in the opposite direction causes the cable capture member 51 to move in the opposite direction thereby releasing the tension on the cable 25.

As shown in FIG. 10, the cable capture member 51 is a generally cylindrical shaft with a threaded hole 51a therein to receive the threaded rod 24. The length of the shaft is only slightly less than the distance between the walls 12, 13 so that it can slide freely between them when the rod is rotated but is prevented from rotating itself. The ends 51b of the shaft are slightly enlarged so that a cable passing over it is prevented from sliding off its ends.

At least one of the walls 33, 34 of the secondary support member 7 is provided with an upstanding boss 52 (see FIGS. 5 and 6) that locates in an arcuately shaped recess 53 (see FIGS. 1 and 9) formed on an inner surface of the link arm 6 attached to that wall. The boss 52 travels along the recess 53 as the secondary support element 7 pivots relative to the link arm 6 until it engages an extreme end of the recess 53 and further pivotal movement is prevented. This limits the angular travel of the link arm 6 in a vertical direction.

It will be appreciated that, when the height of a monitor attached to the secondary support element 7 is adjusted, the link arms 6 rotate about the first pivot axis 27 and the secondary support element 7 rotates about the second pivot axis 42 as the cable 25 extending tightly around the primary and secondary support elements 4,7 maintains the relative orientation of the primary and secondary support elements 4,7 during said adjustment.

As mentioned above, in a preferred embodiment, the control element or cable is endless and extends between and around the primary and secondary support members 4,7. However, in an alternative embodiment, the control element need not be endless and the control element can be pivotally attached at each end to the primary and secondary support members at further pivot points spaced from the first and second pivot points attaching the link arms to the primary and secondary support members. A single or dual upper cable run extending between the primary and secondary support elements 4,7 may be employed. However, it is preferable to provide a second single or dual lower cable run extending between the primary and secondary support elements spaced from the first single or dual cable run in a vertical direction on the opposite side of a line extending between the first and second pivot axes. The second single or dual cable run prevents the secondary support member 5, and a monitor attached thereto, from being rotated so that it points in an upward direction which would not be prevented by the upper cable run—the upper cable run would go slack. However, it will be appreciated that the lower cable run is not essential as the parallelogram operation of the support arm works adequately between the link arm 6 and the upper cable run.

It will be appreciated that a single endless cable is preferred as it avoids additional pivotal connections of the cable to the primary and secondary support members requiring additional components and connections which are subjected to unwanted play between them and increased wear over prolonged use. The preferred embodiment of the present invention provides a monitor support in which free play and wear between components is minimised and which assembly is simplified. The resulting monitor support has a smoother, more fluid movement during height adjustment.

Many modifications and variations of the invention falling within the terms of the following claims will be apparent to those skilled in the art and the foregoing description should be regarded as a description of the preferred embodiments only.

1. A monitor support, comprising:
a primary support member for attachment to a post, wall or other mounting surface;
a rigid link arm extending from the primary support member for rotation relative to the primary support member about a first pivot axis in a vertical plane;
a secondary support member attached to the free end of the link arm for rotation of the secondary support member relative to the link arm about a second pivot axis parallel to the first pivot axis; and
a flexible control element extending between the primary and secondary support members spaced from the first and second pivot axes respectively, the monitor support being configured so that the control element causes the secondary support member to rotate relative to the link arm about the second pivot axis as the link arm rotates relative to the primary support member about the first pivot axis so as to maintain the same relative orientation of the primary and secondary support members.

2. A monitor support according to claim 1, comprising a pair of parallel link arms, both parallel link arms being mounted to the primary and secondary support members for rotation about the first and second axes respectively, and so as to be spaced from each other in an axial direction.

3. A monitor support according to claim 2, wherein the primary and secondary support members extend between and space the parallel link arms from each other in said axial direction.

4. A monitor support according to claim 3, wherein the parallel link arms are configured so that the flexible control element is disposed in the space between said parallel arms and the parallel link arms at least partially conceal said flexible control element.

5. A monitor support according to claim 4, wherein the parallel link arms include upstanding walls extending into the space between said parallel link arms to provide support for the control element extending between the primary and secondary support members.

6. A monitor support according to claim 4, wherein a pair of flexible control elements extend between the primary and secondary support members, said flexible control elements being spaced from each other in an axial direction so that each control element lies adjacent to one of said parallel link arms.

7. A monitor support according to claim 4, wherein the control element is spaced above a line extending between the first and second pivot axes and, a second flexible control element extends between the primary and secondary support members spaced below a line extending between the first and second pivot axes.

8. A monitor support according to claim 7, comprising a first pair of flexible control elements spaced above a line extending between the first and second pivot axes and, a second pair of flexible control elements extending between the primary and secondary support members spaced below a line extending between the first and second pivot axes.

9. A monitor support according to claim 1, wherein the flexible control element is endless and extends around both the primary and secondary support members.

10. A monitor support according to claim 9, wherein the primary support member includes a control element guide to receive and guide the cable around the primary support member.

11. A monitor support according to claim 10, wherein the control element guide is at least partially arcuate in shape so that the control element follows a curved path around the primary support member.

12. A monitor support according to claim 9, wherein the secondary support member includes a control element guide to receive and guide the control element around the secondary support member.

13. A monitor support according to claim 12, wherein the control element guide is at least partially arcuate in shape so that the control element follows a curved path around the secondary support member.

14. A monitor support according to claim 9, wherein the control element is looped around the primary and secondary support members and comprises at least one upper run that extends between the primary and secondary support members and at least one lower run that extends between the primary and secondary support members.

15. A monitor support according to claim 14, wherein the primary support member is configured such that the lower run intersects a vertical plane extending through the first pivot axis at a distance below the first pivot axis and the upper run intersects said vertical plane at a distance above said first pivot axis.

16. A monitor support according to claim 14, wherein the secondary support member is configured so that the lower run intersects a vertical plane extending through the second pivot axis at a distance below the second pivot axis and the upper run intersects said vertical plane at a distance above the second pivot axis.

17. A monitor support according to claim 6, wherein the control element loop is elongated to form two curved ends, an intermediate section between said ends passing around the primary support member with the two curved ends hooked over the secondary support member so that the control element has two upper and two lower runs extending between the primary and secondary support elements.

18. A monitor support according to claim 1, comprising a control element adjustment mechanism for tensioning the control element.

19. A monitor support according to claim 18, wherein the control element adjustment mechanism is mounted on the primary support member.

20. A monitor support according to claim 19, wherein the primary support member includes a recess extending substantially at right angles to the direction of the run of the control element so that the control element bridges the mouth of the recess as it extends over the primary support element.

21. A monitor support according to claim 20, wherein the tension adjustment mechanism includes a tensioning member which can be drawn into the recess against the control member, once a control element has been positioned so as to extend over the mouth of the recess, to pull the control element into the recess to tension the control element.

22. A monitor support according to claim 21, wherein the tension adjustment mechanism includes a threaded rod in engagement with the primary support element that extends beyond the mouth of the recess, the tensioning member being threadingly engaged with the rod so that a control element extending over the mouth of the recess is engaged by the tensioning member as the rod is rotated and the tensioning member is drawn into the recess against the control member.

23. A monitor support according claim 1, including a gas strut extending between the primary and secondary support elements.

24. A monitor support according to claim 23, wherein one end of the gas strut is coupled to a shaft extending coaxial with the first pivot axis on the primary support member.

25. A monitor support according to claim 24, comprising a hook member attached to an end of the gas strut to connect the gas strut to the shaft.

26. A monitor support according to claim 23, wherein one end of the gas strut is pivotally attached to a load adjustment member coupled to the secondary support member.

27. A monitor support according to claim 23, wherein the gas strut is configured to apply a rotational force to the secondary support member which is counteracted by tension in the control member.

28. A monitor support according to claim 27, wherein the load adjustment member is configured to enable said end of the gas strut coupled to it to be moved towards or away from the second pivot axis to adjust the rotational force applied to the secondary support member by the gas strut.

29. A monitor support according to claim 28, wherein a threaded rod extends through the secondary support member and into the load adjustment member so that rotation of said threaded rod moves the end of the gas strut pivotally coupled to the load adjustment member towards or away from the second pivot axis.

30. A monitor support according to claim 1 wherein the link arm and the secondary support element includes cooperating members to limit the rotation of the arm in said vertical plane to within a predetermined angle.

31. A monitor support according to claim 30, wherein the cooperating members comprise a boss on the secondary support element which locates in an arcuately shaped guide groove in the link arm so that rotation of the arm is limited by the extent of the guide groove.

32. A monitor support according to claim 1, wherein the secondary support element includes a mounting shaft for the pivotal attachment of a secondary arm thereto, the monitor being attachable to the free end of the secondary arm.

33. A monitor support according to claim 1, wherein the flexible control element is a cable.

34. A monitor support according to claim 1, wherein the flexible control element is a belt.

35. (canceled)
